(19) United States
(12) Patent Application Publication
(10) Pub. No.: US 2022/0123141 A1
(43) Pub. Date: Apr. 21, 2022

(54) SILICON CARBIDE SEMICONDUCTOR CHIP AND SILICON CARBIDE SEMICONDUCTOR DEVICE

(71) Applicant: SUMITOMO ELECTRIC INDUSTRIES, LTD., Osaka (JP)

(72) Inventors: Mitsuhiko SAKAI, Osaka (JP); Toru HIYOSHI, Osaka (JP)

(21) Appl. No.: 17/429,513

(22) PCT Filed: Jan. 29, 2020
(86) PCT No.: PCT/JP2020/003085

§ 371 Date: Aug. 9, 2021

(30) Foreign Application Priority Data
Feb. 13, 2019 (JP) 2019-023429

(51) Int. Cl. H01L 29/78; H01L 29/16; H01L 21/04; H01L 29/66

(52) U.S. Cl. CPC H01L 29/7813; H01L 29/66068; H01L 21/049; H01L 29/1608

(57) ABSTRACT

A silicon carbide substrate has a first main surface and a second main surface opposite to the first main surface. The first main surface is provided with a gate trench having a side surface and a bottom surface contiguous to the side surface. The gate insulating film is in contact with each of the side surface and the bottom surface. The gate electrode is provided on the gate insulating film. The separation insulating film is provided on the gate electrode. The first electrode is provided on the separation insulating film. The second electrode is provided on the second main surface. The separation insulating film electrically separates the gate electrode and the first electrode from each other. Each of the gate insulating film, the gate electrode, and the separation insulating film, and a portion of the first electrode are provided in the gate trench.

### TECHNICAL FIELD

The present disclosure relates to a silicon carbide semiconductor chip and a silicon carbide semiconductor device. The present application claims a priority based on Japanese Patent Application No. 2019-023429 filed on Feb. 13, 2019, the entire content of which is incorporated herein by reference.

### BACKGROUND ART

Japanese Patent Laying-Open No. 2013-115385 (PTL 1) describes a silicon carbide semiconductor device having a trench gate structure.

### CITATION LIST

### Patent Literature

PTL 1: Japanese Patent Laying-Open No. 2013-115385

### SUMMARY OF INVENTION

A silicon carbide semiconductor chip according to the present disclosure includes a silicon carbide substrate, a first electrode, a second electrode, a gate insulating film, a gate electrode, and a separation insulating film. The silicon carbide substrate has a first main surface and a second main surface opposite to the first main surface. The first main surface is provided with a gate trench having a side surface and a bottom surface contiguous to the side surface. The gate insulating film is in contact with each of the side surface and the bottom surface. The gate electrode is provided on the gate insulating film. The separation insulating film is provided on the gate electrode. The first electrode is provided on the separation insulating film. The second electrode is provided on the second main surface. The separation insulating film electrically separates the gate electrode and the first electrode from each other. Each of the gate insulating film, the gate electrode, and the separation insulating film, and a portion of the first electrode are provided in the gate trench.

### BRIEF DESCRIPTION OF DRAWINGS

FIG. 1 is a schematic side view showing a structure of a silicon carbide semiconductor device.

FIG. 2 is a schematic plan view showing the structure of the silicon carbide semiconductor device.

FIG. 3 is a schematic cross sectional view showing a configuration of a MOSFET included in a silicon carbide semiconductor chip according to the first embodiment.

FIG. 4 is a schematic plan view showing the configuration of the silicon carbide substrate of a MOSFET included in the silicon carbide semiconductor chip according to the first embodiment.

FIG. 5 is a schematic cross sectional view showing a first step of a method of manufacturing the MOSFET included in the silicon carbide semiconductor chip according to the first embodiment.

FIG. 6 is a schematic cross sectional view showing a second step of the method of manufacturing the MOSFET included in the silicon carbide semiconductor chip according to the first embodiment.

FIG. 7 is a schematic cross sectional view showing a third step of the method of manufacturing the MOSFET included in the silicon carbide semiconductor chip according to the first embodiment.

FIG. 8 is a schematic cross sectional view showing a fourth step of the method of manufacturing the MOSFET included in the silicon carbide semiconductor chip according to the first embodiment.

FIG. 9 is a schematic cross sectional view showing a fifth step of the method of manufacturing the MOSFET included in the silicon carbide semiconductor chip according to the first embodiment.

FIG. 10 is a schematic cross sectional view showing a configuration of a MOSFET included in a silicon carbide semiconductor chip according to a second embodiment.

FIG. 11 is a schematic cross sectional view showing a configuration of a MOSFET included in a silicon carbide semiconductor chip according to a third embodiment.

### DETAILED DESCRIPTION

### Problem to be Solved by the Present Disclosure

An object of the present disclosure is to provide a silicon carbide semiconductor chip and a silicon carbide semiconductor device so as to suppress a first electrode from being detached from a silicon carbide substrate.

### Advantageous Effect of the Present Disclosure

According to the present disclosure, there can be provided a silicon carbide semiconductor chip and a silicon carbide semiconductor device so as to suppress a first electrode from being detached from a silicon carbide substrate.

### DESCRIPTION OF EMBODIMENTS

First, embodiments of the present disclosure are listed and described.

Regarding crystallographic indications in the present specification, an individual orientation is represented by [ ], a group orientation is represented by < >, an individual plane is represented by ( ) and a group plane is represented by { }. A crystallographically negative index is normally expressed by putting “−” (bar) above a numeral; however, in the present specification, the crystallographically negative index is expressed by putting a negative sign before the numeral.

(1) A silicon carbide semiconductor chip 200 according to the present disclosure includes a silicon carbide substrate 100, a first electrode 60, a second electrode 63, a gate insulating film 71, a gate electrode 64, and a separation insulating film 72. Silicon carbide substrate 100 has a first main surface 1 and a second main surface 2 opposite to first main surface 1. First main surface 1 is provided with a gate trench 7 having a side surface 5 and a bottom surface 6 contiguous to side surface 5. Gate insulating film 71 is in contact with each of side surface 5 and bottom surface 6. Gate electrode 64 is provided on gate insulating film 71. Separation insulating film 72 is provided on gate electrode 64. First electrode 60 is provided on separation insulating film 72. Second electrode 63 is provided on second main surface 2. Separation insulating film 72 electrically separates gate electrode 64 and first electrode 60 from each other. Each of gate insulating film 71, gate electrode 64, and separation insulating film 72, and a portion of first electrode 60 are provided in gate trench 70.

(2) In silicon carbide semiconductor chip 200 according to (1), side surface 5 may have: a first side surface portion 51 in contact with gate insulating film 71 and contiguous to bottom surface 6; a second side surface portion 52 in contact with separation insulating film 72 and contiguous to first side surface portion 51; and a third side surface portion 53 located between second side surface portion 52 and first main surface 1. First electrode 60 may have a silicide film 61 and a metal film 62 provided on silicide film 61. Silicide film 61 may be in contact with each of first main surface 1 and third side surface portion 53.

(3) In silicon carbide semiconductor chip 200 according to (1) or (2), separation insulating film 72 includes silicon nitride or silicon oxynitride. Gate insulating film 71 may include silicon dioxide.

(4) In silicon carbide semiconductor chip 200 according to any one of (1) to (3), separation insulating film 72 may be curved to protrude toward bottom surface 6.

(5) In silicon carbide semiconductor chip 200 according to any one of (1) to (4), silicon carbide substrate 100 may include: a first impurity region 10 having a first conductivity type; a second impurity region 30 provided on first impurity region 10 and having a second conductivity type different from the first conductivity type; and a third impurity region 40 provided on second impurity region 30 so as to be separated from first impurity region 10, third impurity region 40 having the first conductivity type. Separation insulating film 72 may be in contact with third impurity region 40 at side surface 5.

(6) A silicon carbide semiconductor device 300 according to the present disclosure includes: silicon carbide semiconductor chip 200 according to any one of (1) to (5); a first wire 21 electrically connected to first electrode 60; and a second wire 22 electrically connected to gate electrode 64.

### Details of Embodiments of the Present Disclosure

Hereinafter, details of the embodiments of the present disclosure will be described. In the description below, the same or corresponding elements are denoted by the same reference characters, and will not be described repeatedly.

### First Embodiment

First, a configuration of a silicon carbide semiconductor device 300 according to a first embodiment will be described.

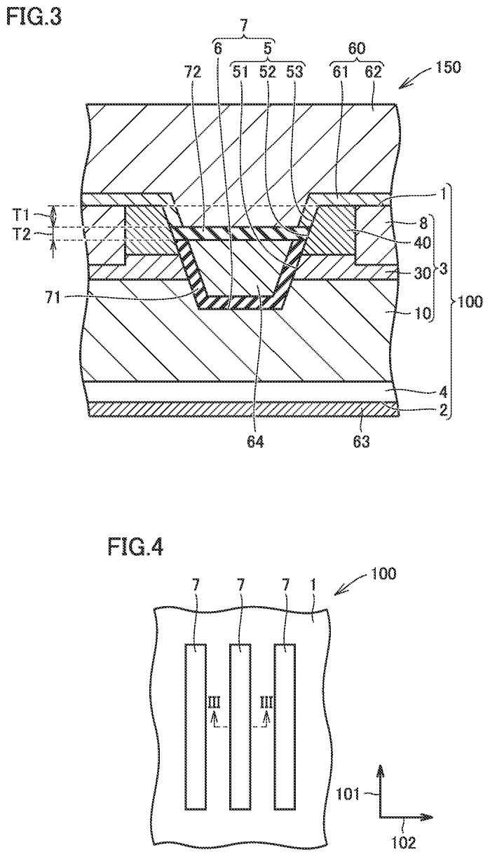

As shown in FIG. 1, silicon carbide semiconductor device 300 according to the first embodiment mainly includes a silicon carbide semiconductor chip 200, a lead frame 20, a first wire 21, and a second wire 22. Silicon carbide semiconductor chip 200 is provided on lead frame 20. First wire 21 is configured such that current can be applied to a first electrode 60 (see FIG. 3) described later. One end portion of first wire 21 is connected to silicon carbide semiconductor chip 200. The other end portion of first wire 21 is connected to lead frame 20. Second wire 22 is configured such that current can be applied to a gate electrode 64 (see FIG. 3) described later. One end portion of second wire 22 is connected to silicon carbide semiconductor chip 200. The other end portion of second wire 22 is connected to lead frame 20. First wire 21 and second wire 22 are electrically insulated from each other.

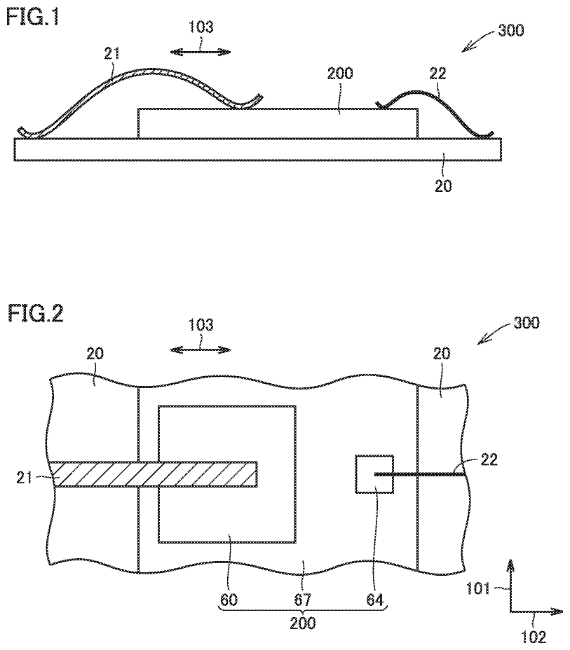

As shown in FIG. 2, silicon carbide semiconductor chip 200 includes first electrode 60, gate electrode 64, and a passivation film 67. The one end portion of first wire 21 is in contact with first electrode 60. The one end portion of second wire 22 is electrically connected to gate electrode 64. Passivation film 67 is located between first electrode 60 and gate electrode 64. As shown in FIG. 2, when viewed in a direction perpendicular to a main surface of silicon carbide semiconductor chip 200, the extending direction of first wire 21 is, for example, a second direction 102. In other words, when viewed in the direction perpendicular to the main surface of silicon carbide semiconductor chip 200, the long side direction of first wire 21 is second direction 102. Similarly, when viewed in the direction perpendicular to the main surface of silicon carbide semiconductor chip 200, the extending direction of second wire 22 is, for example, second direction 102. In other words, when viewed in the direction perpendicular to the main surface of silicon carbide semiconductor chip 200, the long side direction of second wire 22 is second direction 102.

First direction 101 is, for example, a <11-20> direction. Second direction 102 is, for example, a <1-100> direction. First direction 101 may be, for example, a direction obtained by projecting the <11-20> direction onto the main surface of silicon carbide semiconductor chip 200. Second direction 102 may be, for example, a direction obtained by projecting the <1-100> direction onto the main surface of silicon carbide semiconductor chip 200. It should be noted that first direction 101 may be the <1-100> direction, and second direction 102 may be the <11-20> direction. Each of first direction 101 and second direction 102 is parallel to the main surface of silicon carbide semiconductor chip 200.

Next, a configuration of silicon carbide semiconductor chip 200 according to the first embodiment will be described.

Silicon carbide semiconductor chip 200 according to the first embodiment includes, for example, a MOSFET (Metal Oxide Semiconductor Field Effect Transistor). As shown in FIG. 3, a MOSFET 150 mainly includes a silicon carbide substrate 100, a gate electrode 64, a gate insulating film 71, a separation insulating film 72, a source electrode 60 (first electrode 60), and a drain electrode 63 (second electrode 63). Silicon carbide substrate 100 has a first main surface 1 and a second main surface 2 opposite to first main surface 1. Silicon carbide substrate 100 includes a silicon carbide single crystal substrate 4 and a silicon carbide epitaxial layer 3 provided on silicon carbide single crystal substrate 4. Silicon carbide single crystal substrate 4 constitutes second main surface 2. Silicon carbide epitaxial layer 3 constitutes first main surface 1.

First main surface 1 of silicon carbide substrate 100 corresponds to, for example, a {0001} plane or a plane angled off by less than or equal to 8° with respect to the {0001} plane. Specifically, first main surface 1 corresponds to, for example, a (0001) plane or a plane angled off by less than or equal to 8° with respect to the (0001) plane. First main surface 1 may correspond to, for example, a (000-1) plane or a plane angled off by less than or equal to 8° with respect to the (000-1) plane. Silicon carbide single crystal substrate 4 is composed of, for example, hexagonal silicon carbide having a polytype of 4H. The thickness of silicon carbide single crystal substrate 4 is, for example, 350 μm, or is less than or equal to 500 μm.

Silicon carbide epitaxial layer 3 mainly includes a drift region 10 (first impurity region 10), a body region 30 (second impurity region 30), a source region 40 (third impurity region 40), and a contact region 8. Drift region 10 is provided on silicon carbide single crystal substrate 4. Drift region 10 includes an n type impurity such as nitrogen (N), and has an n type conductivity type (first conductivity type). The concentration of the n type impurity in drift region 10 may be lower than the concentration of the n type impurity in silicon carbide single crystal substrate 4.

Body region 30 is provided on drift region 10. Body region 30 includes a p type impurity such as aluminum (Al) and has a p type conductivity (second conductivity type) different from the n type conductivity. The concentration of the p type impurity in body region 30 may be higher than the concentration of the n type impurity in drift region 10. Body region 30 is spaced apart from each of first main surface 1 and second main surface 2.

Source region 40 is provided on body region 30 so as to be separated from drift region 10 by body region 30. Source region 40 includes an n type impurity such as nitrogen or phosphorus (P), and has the n type conductivity. Source region 40 constitutes a portion of first main surface 1. The concentration of the n type impurity in source region 40 may be higher than the concentration of the p type impurity in body region 30. The concentration of the n type impurity in source region 40 is, for example, about 1×10¹⁹ cm⁻³.

Contact region 8 includes a p type impurity such as aluminum, and has the p type conductivity. The concentration of the p type impurity in contact region 8 may be higher than the concentration of the p type impurity in body region 30. Contact region 8 may extend through source region 40 and may be in contact with body region 30. Contact region 8 constitutes a portion of first main surface 1. The concentration of the p type impurity in contact region 8 is, for example, more than or equal to 1×10¹⁸ cm⁻³ and less than or equal to 1×10²⁰ cm⁻³.

As shown in FIG. 3, first main surface 1 is provided with gate trenches 7. Each of gate trenches 7 has a side surface 5 and a bottom surface 6. Side surface 6 is contiguous to side surface 5. Side surface 5 is contiguous to first main surface 1. Side surface 5 includes a first side surface portion 51, a second side surface portion 52, and a third side surface portion 53. First side surface portion 51 is in contact with gate insulating film 71. First side surface portion 51 is contiguous to bottom surface 6. First side surface portion 51 is constituted of first impurity region 10, second impurity region 30, and third impurity region 40.

Second side surface portion 52 is in contact with separation insulating film 72. Second side surface portion 52 is contiguous to first side surface portion 51. Second side surface portion 52 is located between first side surface portion 51 and third side surface portion 53. Third side surface portion 53 is located between second side surface portion 52 and first main surface 1. Third side surface portion 53 is contiguous to each of second side surface portion 52 and first main surface 1. Each of second side surface portion 52 and third side surface portion 53 is constituted of third impurity region 40.

Gate insulating film 71 includes, for example, silicon dioxide (SiO₂). Gate insulating film 71 is in contact with each of side surface 5 and bottom surface 6. Gate insulating film 71 is in contact with each of first impurity region 10, second impurity region 30, and third impurity region 40 at side surface 5. Gate insulating film 71 is in contact with first impurity region 10 at bottom surface 6. Second impurity region 30 in contact with gate insulating film 71 is configured such that a channel can be formed. The thickness of gate insulating film 71 is, for example, more than or equal to 40 nm and less than or equal to 150 nm.

Gate electrode 64 is provided on gate insulating film 71. Gate electrode 64 is disposed in contact with gate insulating film 71. Gate electrode 64 is provided to fill a groove formed by gate insulating film 71. Gate electrode 64 is composed of, for example, a conductor such as polysilicon doped with an impurity.

Separation insulating film 72 is provided on gate electrode 64. Separation insulating film 72 electrically separates first electrode 60 and gate electrode 64 from each other. Separation insulating film 72 is disposed between first electrode 60 and gate electrode 64. Separation insulating film 72 is provided to cover gate electrode 64. Separation insulating film 72 is in contact with each of gate electrode 64 and gate insulating film 71. Separation insulating film 72 is composed of, for example, silicon nitride (SiN), silicon oxynitride (SiON), or silicon dioxide (SiO₂) including an impurity. Separation insulating film 72 may be in contact with third impurity region 40 at side surface 5. The thickness (second thickness T2) of separation insulating film 72 is, for example, 0.2 μm. Second thickness T2 may be more than or equal to 0.1 μm and less than or equal to 0.3 μm, for example.

Each of gate insulating film 71, gate electrode 64, and separation insulating film 72 is provided in gate trench 7. From a different point of view, it can be said that in a direction perpendicular to second main surface 2, each of gate insulating film 71, gate electrode 64, and separation insulating film 72 is located between second main surface 2 and first main surface 1. In the direction perpendicular to second main surface 2, each of gate insulating film 71, gate electrode 64, and separation insulating film 72 is provided on the second main surface 2 side with respect to first main surface 1.

First electrode 60 is provided on first main surface 1. First electrode 60 is in contact with third impurity region 40 at first main surface 1. First electrode 60 may be in contact with contact region 8 at first main surface 1. First electrode 60 is provided on separation insulating film 72. A portion of first electrode 60 is provided in gate trench 7. A portion of first electrode 60 is located in gate trench 7. The thickness (first thickness T1) of the portion of first electrode 60 located in gate trench 7 is, for example, 0.1 μm. First thickness T1 may be more than or equal to 0.05 μm and less than or equal to 0.3 μm, for example. First electrode 60 is in contact with separation insulating film 72 in gate trench 7.

First electrode 60 is, for example, a source electrode. First electrode 60 includes a silicide film 61 and a metal film 62. Metal film 62 is provided on silicide film 61. Silicide film 61 includes, for example, nickel silicide (NiSi) or titanium aluminum silicide (TiAlSi). Silicide film 61 is in contact with each of first main surface 1 and third side surface portion 53. Silicide film 61 is in contact with third impurity region 40 at first main surface 1. Silicide film 61 may be in contact with contact region 8 at first main surface 1. Silicide film 61 may be in contact with third impurity region 40 at third side surface portion 53.

Metal film 62 is a source wiring. Metal film 62 includes, for example, aluminum (Al). Metal film 62 may include copper (Cu). Each of silicide film 61 and metal film 62 may be in contact with separation insulating film 72 in gate trench 7.

Second electrode 63 is provided on second main surface 2. Second electrode 63 is a drain electrode. Second electrode 63 is in contact with silicon carbide single crystal substrate 4 at second main surface 2. Second electrode 63 is electrically connected to first impurity region 10 on the second main surface 2 side. Second electrode 63 is composed of a material allowing for ohmic contact with n type silicon carbide single crystal substrate 4. Examples of the material include NiSi (nickel silicide). Second electrode 63 is electrically connected to silicon carbide single crystal substrate 4.

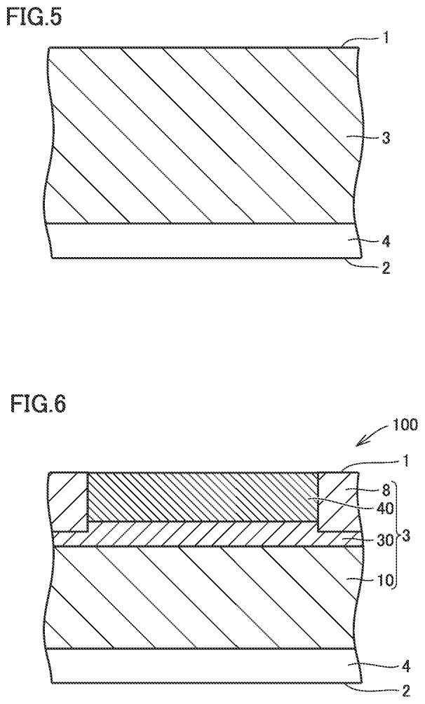

As shown in FIG. 4, when viewed in a direction perpendicular to first main surface 1, gate trench 7 may have a substantially rectangular shape. Gate trench 7 extends along first direction 101. First direction 101 is the long side direction of gate trench 7. Second direction 102 is the short side direction of gate trench 7. The plurality of gate trenches 7 are arranged in parallel along second direction 102. It should be noted that the cross section of FIG. 3 corresponds to a cross section taken along a line III-III of FIG. 4.

Next, an operation of MOSFET 150 according to the present embodiment will be described. When voltage is applied between source electrode 60 and drain electrode 63 in a state in which voltage applied to gate electrode 64 is less than a threshold voltage, i.e., in an off state, a pn junction between second impurity region 30 and first impurity region 10 is reverse-biased, thus resulting in a non-conductive state. On the other hand, when voltage of more than or equal to the threshold voltage is applied to gate electrode 64, an inversion layer is formed in a channel region near a contact of second impurity region 30 with gate insulating film 71. As a result, second impurity region 30 and first impurity region 10 are electrically connected to each other, with the result that current flows between source electrode 60 and drain electrode 63. In this way, MOSFET 150 is operated.

Next, a method of manufacturing MOSFET 150 according to the present embodiment will be described.

First, a step of preparing silicon carbide substrate 100 is performed. For example, a silicon carbide ingot (not shown) manufactured by a sublimation method is sliced to prepare silicon carbide single crystal substrate 4. The maximum diameter of silicon carbide single crystal substrate 4 is, for example, more than or equal to 100 mm, and is preferably more than or equal to 150 mm.

Next, a step of forming silicon carbide epitaxial layer 3 is performed. For example, silicon carbide epitaxial layer 3 is formed by epitaxial growth on silicon carbide single crystal substrate 4 by a CVD (Chemical Vapor Deposition) method by using a mixed gas of silane (SiH₄) and propane (C₃H₈) as a source material gas and by using hydrogen (H₂) as a carrier gas (see FIG. 5). During the epitaxial growth, an n type impurity such as nitrogen is introduced into silicon carbide epitaxial layer 3.

Next, an ion implantation step is performed. For example, ions of a p type impurity such as aluminum are implanted into silicon carbide epitaxial layer 3. In this way, body region 30 is formed. Next, ions of an n type impurity such as phosphorus are implanted into body region 30. In this way, source region 40 is formed. Next, a mask layer (not shown) is formed which is provided with an opening above a region in which contact region 8 is to be formed. Next, a p type impurity such as aluminum is implanted into source region 40. In this way, contact region 8 in contact with each of source region 40 and body region 30 is formed (see FIG. 6).

Next, activation annealing is performed to activate the impurity ions implanted in silicon carbide substrate 100. The temperature of the activation annealing is preferably more than or equal to 1500° C. and less than or equal to 1900° C., and is, for example, about 1700° C. The activation annealing time is, for example, about 30 minutes. The activation annealing atmosphere is preferably an inert gas atmosphere such as an Ar atmosphere. In this way, silicon carbide substrate 100 is prepared. Silicon carbide substrate 100 has first main surface 1 and second main surface 2. Source region 40 and contact region 8 constitute first main surface 1.

Next, a step of forming gate trench 7 is performed. First, silicon carbide substrate 100 is etched in a state in which mask layer 31 is formed on first main surface 1. Specifically, for example, a portion of source region 40 and a portion of body region 30 are removed by the etching. As an etching method, for example, reactive ion etching, particularly, inductively coupled plasma reactive ion etching can be used. For example, it is possible to use inductively coupled plasma reactive ion etching that employs sulfur hexafluoride (SF₆) or a mixed gas of SF₆ and oxygen (O₂) as a reaction gas. By the etching, a recess is formed at a region at which gate trench 7 is to be formed. The recess has: a side portion substantially perpendicular to first main surface 1; and a bottom provided to be contiguous to the side portion and substantially parallel to first main surface 1.

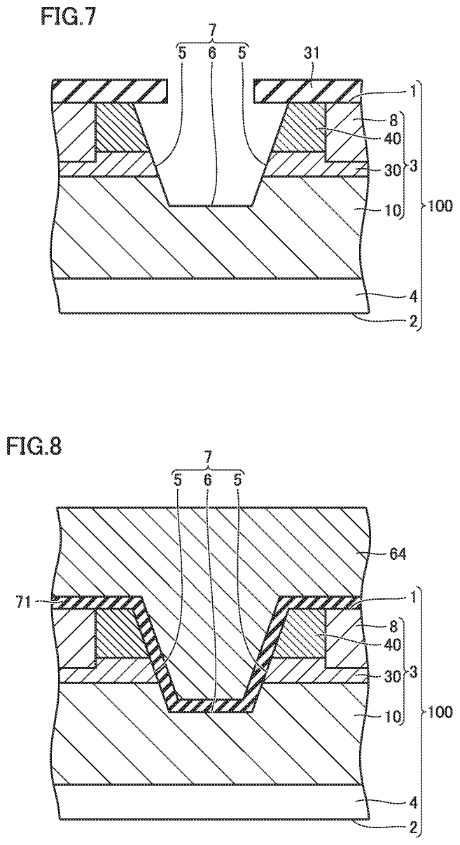

Next, thermal etching is performed in the recess. The thermal etching may be performed by performing heating in an atmosphere including a reactive gas having at least one or more types of halogen atoms in the state in which mask layer 31 is formed on first main surface 1. The at least one or more types of halogen atoms include at least either of chlorine (Cl) atoms and fluorine (F) atoms. The atmosphere includes, for example, chlorine (Cl₂), boron trichloride (BCl₃), SF₆, or carbon tetrafluoride (CF₄). For example, the thermal etching is performed at a heat treatment temperature of, for example, more than or equal to 800° C. and less than or equal to 900° C. by using a mixed gas of chlorine gas and oxygen gas as a reaction gas. It should be noted that the reaction gas may include a carrier gas in addition to the chlorine gas and the oxygen gas. As the carrier gas, nitrogen gas, argon gas, helium gas, or the like can be used, for example. By the thermal etching, gate trench 7 is formed in first main surface 1 of silicon carbide substrate 100 (see FIG. 7).

Side surface 5 extends through source region 40 and body region 30 to reach drift region 10. From a different point of view, it can be said that side surface 5 is constituted of source region 40, body region 30, and drift region 10. Bottom surface 6 is located in drift region 10. From a different point of view, it can be said that bottom surface 6 is constituted of drift region 10. Bottom surface 6 is, for example, a flat surface parallel to second main surface 2. As shown in FIG. 7, in a cross section perpendicular to the long side direction of gate trench 7, the width of gate trench 7 is increased in a direction from bottom surface 6 toward first main surface 1.

Next, a step of forming gate insulating film 71 is performed. For example, silicon carbide substrate 100 is thermally oxidized to form gate insulating film 71 in contact with source region 40, body region 30, drift region 10, contact region 8, and first main surface 1. Specifically, silicon carbide substrate 100 is heated in an atmosphere including oxygen at a temperature of, for example, more than or equal to 1300° C. and less than or equal to 1400° C. In this way, gate insulating film 71 in contact with gate trench 7 is formed.

Next, silicon carbide substrate 100 may be subjected to heat treatment (NO annealing) in a nitrogen monoxide (NO) gas atmosphere. In the NO annealing, silicon carbide substrate 100 is held at more than or equal to 1100° C. and less than or equal to 1400° C. for about 1 hour, for example. In this way, nitrogen atoms are introduced into an interface region between gate insulating film 71 and body region 30. As a result, formation of interface states in the interface region is suppressed, thereby achieving improved channel mobility.

After the NO annealing, Ar annealing may be performed using argon (Ar) as an atmospheric gas. The heating temperature of the Ar annealing is, for example, more than or equal to the heating temperature of the NO annealing. The Ar annealing time is, for example, about 1 hour. In this way, the formation of interface states in the interface region between gate insulating film 71 and body region 30 is further suppressed. It should be noted that instead of the Ar gas, another inert gas such as nitrogen gas may be employed as the atmospheric gas.

Next, a step of forming gate electrode 64 is performed. Gate electrode 64 is formed on gate insulating film 71. Gate electrode 64 is formed by, for example, an LP-CVD (Low Pressure Chemical Vapor Deposition) method. Gate electrode 64 is formed to fill the groove formed by gate insulating film 71. Gate electrode 64 is formed to face each of source region 40, body region 30, and drift region 10 (see FIG. 8).

Next, portions of gate insulating film 71 and gate electrode 64 are removed. Specifically, each of gate insulating film 71 and gate electrode 64 on first main surface 1 and portions of gate insulating film 71 and gate electrode 64 provided in gate trench 7 are removed by, for example, dry etching. In this way, first main surface 1 and a portion of side surface 5 are exposed from gate insulating film 71.

Next, a step of forming separation insulating film 72 is performed. Specifically, separation insulating film 72 is formed to cover gate electrode 64 in gate trench 7. Separation insulating film 72 is formed by, for example, the CVD (Chemical Vapor Deposition) method. Separation insulating film 72 may be formed by an atmospheric pressure CVD method, a plasma CVD method, or a low pressure CVD method. Separation insulating film 72 is, for example, a material including silicon dioxide. Separation insulating film 72 is in contact with each of gate electrode 64 and gate insulating film 71 in gate trench 7.

Next, a step of forming first electrode 60 is performed. For example, electrode film 61 is formed in contact with each of source region 40 and contact region 8 at first main surface 1 and in contact with source region 40 at side surface 5. Electrode film 61 is formed by, for example, a sputtering method. Electrode film 61 is composed of a material including Ti, Al, and Si, for example.

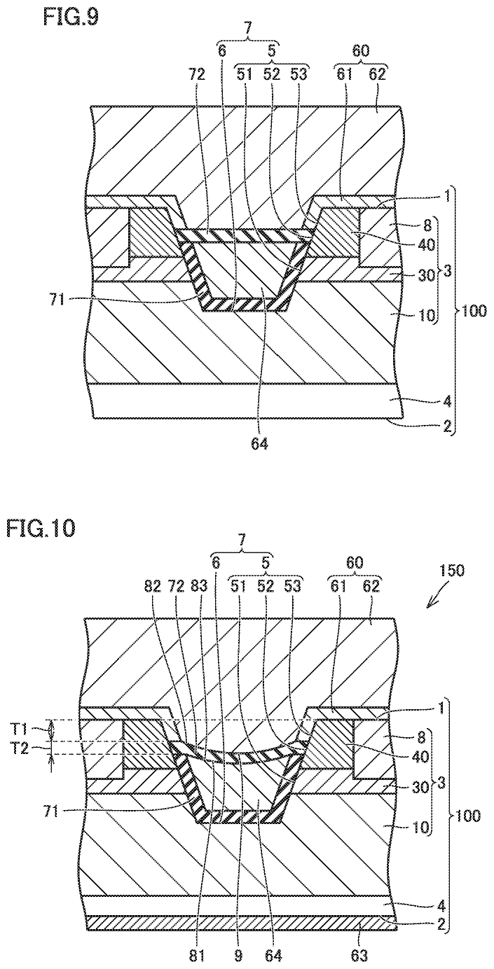

Next, electrode film 61 is held at a temperature of, for example, more than or equal to 900° C. and less than or equal to 1100° C. for about 5 minutes. In this way, at least a portion of electrode film 61 reacts with silicon included in silicon carbide substrate 100, thus resulting in silicidation. In this way, electrode film 61 in ohmic contact with source region 40 is formed. Electrode film 61 may be in ohmic contact with contact region 8. In this way, silicide film 61 in contact with each of first main surface 1 and side surface 5 is formed. Next, metal film 62 is formed. Metal film 62 is formed on each of silicide film 61 and separation insulating film 72. Metal film 62 includes, for example, aluminum. Metal film 62 may include copper. A portion of metal film 62 is formed to be located in gate trench 7. In this way, first electrode 60 including silicide film 61 and metal film 62 is formed (see FIG. 9).

Next, backside surface polishing is performed at second main surface 2 of silicon carbide substrate 100. In this way, the thickness of silicon carbide substrate 100 is reduced. Next, a step of forming second electrode 63 is performed. For example, second electrode 63 in contact with second main surface 2 is formed by the sputtering method. Second electrode 63 is composed of, for example, a material including NiSi or TiAlSi. In this way, MOSFET 150 (FIG. 3) according to the present embodiment is completed.

In the above-described embodiment, it has been illustrated that the n type corresponds to the first conductivity type and the p type corresponds to the second conductivity type; however, the p type may correspond to the first conductivity type and the n type may correspond to the second conductivity type. Further, in the above-described embodiment, the MOSFET has been illustratively described as a transistor included in silicon carbide semiconductor chip 200; however, the transistor included in silicon carbide semiconductor chip 200 may be, for example, an IGBT (Insulated Gate Bipolar Transistor) or the like. When the transistor included in silicon carbide semiconductor chip 200 is an IGBT, the first electrode corresponds to an emitter electrode, and the second electrode corresponds to a collector electrode. The position of an interface (i.e., PN interface) between a p type region and an n type region can be specified by, for example, an SCM (Scanning Capacitance Microscope).

### Second Embodiment

Next, a configuration of a MOSFET 150 included in a silicon carbide semiconductor chip 200 according to a second embodiment will be described. MOSFET 150 according to the second embodiment is different from MOSFET 150 according to the first embodiment mainly in terms of the following configuration: separation insulating film 72 is curved to protrude toward bottom surface 6. The other configurations of MOSFET 150 according to the second embodiment are the same as those of MOSFET 150 according to the first embodiment. The following mainly describes the configuration different from that of MOSFET 150 according to the first embodiment.

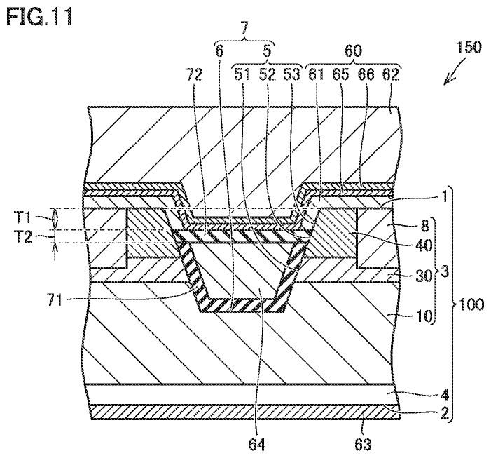

As shown in FIG. 10, in MOSFET 150 according to the second embodiment, separation insulating film 72 is curved to protrude toward bottom surface 6. First electrode 60 has a contact surface 9 in contact with separation insulating film 72. Contact surface 9 may be curved to protrude toward bottom surface 6. Contact surface 9 is constituted of, for example, electrode film 61. Separation insulating film 72 has a third main surface 82 and a fourth main surface 81. Fourth main surface 81 is located opposite to third main surface 82. Third main surface 82 is in contact with first electrode 60. Fourth main surface 81 is in contact with each of gate insulating film 71 and gate electrode 64. Third main surface 82 has a recessed shape. Third main surface 82 is curved to be recessed toward bottom surface 6. Fourth main surface 81 has a protruding shape. Fourth main surface 81 is curved to protrude toward bottom surface 6. Gate electrode 64 has a fifth main surface 83. Fifth main surface 83 is in contact with separation insulating film 72. Fifth main surface 83 has a recessed shape. Fifth main surface 83 is curved to be recessed toward bottom surface 6.

### Third Embodiment

Next, a configuration of a MOSFET 150 included in a silicon carbide semiconductor chip 200 according to a third embodiment will be described. MOSFET 150 according to the third embodiment is different from MOSFET 150 according to the first embodiment mainly in terms of the following configuration: first electrode 60 includes silicide film 61, metal film 62, a titanium film 65, and a titanium nitride film 66. The other configurations of MOSFET 150 according to the third embodiment are the same as those of MOSFET 150 according to the first embodiment. The following mainly describes the configuration different from MOSFET 150 according to the first embodiment.

As shown in FIG. 11, in MOSFET 150 according to the third embodiment, first electrode 60 includes silicide film 61, metal film 62, titanium film 65, and titanium nitride film 66. Titanium film 65 is provided on silicide film 61. Titanium film 65 is in contact with silicide film 61. Titanium film 65 may be disposed in gate trench 7. Titanium film 65 may be in contact with each of separation insulating film 72 and silicide film 61 in gate trench 7.

Titanium nitride film 66 is provided on titanium film 65. Titanium nitride film 66 is in contact with titanium film 65. Titanium nitride film 66 may be disposed in gate trench 7. Titanium nitride film 66 may be in contact with titanium film 65 in gate trench 7. Metal film 62 is provided on titanium nitride film 66. Metal film 62 is in contact with titanium nitride film 66. Metal film 62 may be disposed in gate trench 7. Metal film 62 may be in contact with titanium nitride film 66 in gate trench 7.

Next, functions and effects of silicon carbide semiconductor chip 200 and silicon carbide semiconductor device 300 according to the above-described embodiments will be described.

In silicon carbide semiconductor device 300, generally, silicon carbide semiconductor chip 200 and lead frame 20 are electrically connected to each other by wire bonding. Specifically, the source wire (first wire 21) is connected to the source electrode (first electrode 60). When connecting first wire 21 to first electrode 60, ultrasonic wave is applied to first wire 21. The main vibration direction of the ultrasonic wave is a third direction 103 (see FIGS. 1 and 2). Third direction 103 is a direction which is parallel to first main surface 1 and in which first wire 21 extends when viewed in the direction perpendicular to first main surface 1 (see FIG. 2).

When connecting first wire 21 to first electrode 60 by the wire bonding, the vibration in third direction 103 is also applied to first electrode 60. On this occasion, first electrode 60 may be detached from silicon carbide substrate 100. In particular, when performance of the power device is improved and a large amount of current can flow in first electrode 60, the diameter of first wire 21 needs to be large. For example, when the diameter of first wire 21 is made large to more than or equal to about 400 μm, large load, output and frequency of the ultrasonic wave, and the like are applied to first wire 21 during the wire bonding. As a result, the vibration applied to first electrode 60 becomes large, with the result that first electrode 60 is likely to be detached from silicon carbide substrate 100. When the load and the output and frequency of the ultrasonic wave are reduced, bonding strength between first wire 21 and first electrode 60 becomes weak, with the result that detachment occurs at the interface therebetween.

According to silicon carbide semiconductor device 300 according to the embodiment, first electrode 60 is provided on separation insulating film 72, and has the portion provided in gate trench 7. Since the portion of first electrode 60 is thus located in gate trench 7, first electrode 60 is held in gate trench 7 (anchor effect). Therefore, even when vibration is applied to first electrode 60 during the wire bonding, first electrode 60 can be suppressed from being detached from silicon carbide substrate 100.

Further, according to silicon carbide semiconductor device 300 according to the embodiment, silicide film 61 is in contact with each of first main surface 1 and third side surface portion 53. Therefore, contact resistance between silicide film 61 and silicon carbide substrate 100 can be reduced as compared with a case where silicide film 61 is in contact with only first main surface 1.

Further, according to silicon carbide semiconductor device 300 according to the embodiment, separation insulating film 72 may include silicon nitride or silicon oxynitride. Gate insulating film 71 may include silicon dioxide. Each of silicon nitride and silicon oxynitride has higher insulating performance than that of silicon dioxide. This leads to improved insulating property between first electrode 60 and gate electrode 64.

Further, according to silicon carbide semiconductor device 300 according to the embodiment, separation insulating film 72 may be curved to protrude toward bottom surface 6. In this way, first electrode 60 is located in the recess of separation insulating film 72. Therefore, first electrode 60 can be further suppressed from being detached from silicon carbide substrate 100.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first main surface; 2: second main surface; 3: silicon carbide epitaxial layer; 4: silicon carbide single crystal substrate; 5: side surface; 6: bottom surface; 7: gate trench; 8: contact region; 9: contact surface; 10: first impurity region (drift region); 20: lead frame; 21: first wire; 22: second wire; 30: second impurity region (body region); 31: mask layer; 40: third impurity region (source region); 51: first side surface portion; 52: second side surface portion; 53: third side surface portion; 60: first electrode (source electrode); 61: silicide film (electrode film); 62: metal film; 63: second electrode (drain electrode); 64: gate electrode; 65: titanium film; 66: titanium nitride film; 67: passivation film; 71: gate insulating film; 72: separation insulating film; 81: fourth main surface; 82: third main surface; 83: fifth main surface; 100: silicon carbide substrate; 101: first direction; 102: second direction; 103: third direction; 150: MOSFET; 200: silicon carbide semiconductor chip; 300: silicon carbide semiconductor device; T1: first thickness; T2: second thickness.

1. A silicon carbide semiconductor chip comprising:
a silicon carbide substrate having a first main surface and a second main surface opposite to the first main surface, the first main surface being provided with a gate trench having a side surface and a bottom surface contiguous to the side surface;
a gate insulating film in contact with each of the side surface and the bottom surface;
a gate electrode provided on the gate insulating film;
an separation insulating film provided on the gate electrode;
a first electrode provided on the separation insulating film; and
a second electrode provided on the second main surface, wherein
the separation insulating film electrically separates the gate electrode and the first electrode from each other, and
each of the gate insulating film, the gate electrode, and the separation insulating film, and a portion of the first electrode are provided in the gate trench.

2. The silicon carbide semiconductor chip according to claim 1, wherein
the side surface has
a first side surface portion in contact with the gate insulating film and contiguous to the bottom surface,
a second side surface portion in contact with the separation insulating film and contiguous to the first side surface portion, and
a third side surface portion located between the second side surface portion and the first main surface,
the first electrode has a silicide film and a metal film provided on the silicide film, and
the silicide film is in contact with each of the first main surface and the third side surface portion.

3. The silicon carbide semiconductor chip according to claim 1, wherein
the separation insulating film includes silicon nitride or silicon oxynitride, and
the gate insulating film includes silicon dioxide.

4. The silicon carbide semiconductor chip according to claim 1, wherein the separation insulating film is curved to protrude toward the bottom surface.

5. The silicon carbide semiconductor chip according to claim 1, wherein
the silicon carbide substrate includes
a first impurity region having a first conductivity type,
a second impurity region provided on the first impurity region and having a second conductivity type different from the first conductivity type, and
a third impurity region provided on the second impurity region so as to be separated from the first impurity region, the third impurity region having the first conductivity type, and
the separation insulating film is in contact with the third impurity region at the side surface.

6. A silicon carbide semiconductor device comprising:
the silicon carbide semiconductor chip according to claim 1;
a first wire electrically connected to the first electrode; and
a second wire electrically connected to the gate electrode.

7. A silicon carbide semiconductor chip comprising:
a silicon carbide substrate having a first main surface and a second main surface opposite to the first main surface, the first main surface being provided with a gate trench having a side surface and a bottom surface contiguous to the side surface;
a gate insulating film in contact with each of the side surface and the bottom surface;
a gate electrode provided on the gate insulating film;
an separation insulating film provided on the gate electrode;
a first electrode provided on the separation insulating film; and
a second electrode provided on the second main surface, wherein
the separation insulating film electrically separates the gate electrode and the first electrode from each other, and
each of the gate insulating film, the gate electrode, and the separation insulating film, and a portion of the first electrode are provided in the gate trench,
wherein the side surface has
a first side surface portion in contact with the gate insulating film and contiguous to the bottom surface,
a second side surface portion in contact with the separation insulating film and contiguous to the first side surface portion, and
a third side surface portion located between the second side surface portion and the first main surface,
the first electrode has a silicide film and a metal film provided on the silicide film, and
the silicide film is in contact with each of the first main surface and the third side surface portion.

8. A silicon carbide semiconductor device comprising:
a silicon carbide semiconductor chip including
a silicon carbide substrate having a first main surface and a second main surface opposite to the first main surface, the first main surface being provided with a gate trench having a side surface and a bottom surface contiguous to the side surface;
a gate insulating film in contact with each of the side surface and the bottom surface;
a gate electrode provided on the gate insulating film;
an separation insulating film provided on the gate electrode;
a first electrode provided on the separation insulating film; and
a second electrode provided on the second main surface, wherein
the separation insulating film electrically separates the gate electrode and the first electrode from each other, and
each of the gate insulating film, the gate electrode, and the separation insulating film, and a portion of the first electrode are provided in the gate trench,
wherein the side surface has
a first side surface portion in contact with the gate insulating film and contiguous to the bottom surface,
a second side surface portion in contact with the separation insulating film and contiguous to the first side surface portion, and
a third side surface portion located between the second side surface portion and the first main surface,
the first electrode has a silicide film and a metal film provided on the silicide film, and
the silicide film is in contact with each of the first main surface and the third side surface portion;
a first wire electrically connected to the first electrode; and
a second wire electrically connected to the gate electrode.
